(19) United States
(12) Patent Application Publication
(10) Pub. No.: US 2011/0263052 A1
(43) Pub. Date: Oct. 27, 2011

(54) METHOD OF REMOVING CONTAMINATIONS

(76) Inventor: Xintuo Dai, Singapore (SG)

(21) Appl. No.: 12/767,815

(22) Filed: Apr. 27, 2010

(51) Int. Cl. H01L 21/66

(52) U.S. Cl. 438/16; 438/14; 257/E21.53

(57) ABSTRACT

A method of removing contaminations includes providing a wafer, performing an inspection or a measuring step to the wafer, and performing a baking step to re-vaporize and remove contaminations from the wafer after the inspection or measuring step.

### BACKGROUND OF THE INVENTION

1. Field of the Invention

The present invention related generally to a method of removing contaminations from a wafer, and more particularly, to a method of removing organic contaminations induced in the inspection or measuring steps from a wafer.

2. Description of the Prior Art

In the fabrication of semiconductor devices such as integrated circuits (ICs), memory cells, and the like, a series of manufacturing operations are performed to define features on semiconductor wafers. In other words, the wafer includes IC devices in the form of multi-level structures defined on a silicon substrate.

During the series of manufacturing operations, the wafer surface is exposed to various types of contaminants. Essentially, any material present in a manufacturing operation is a potential source of contamination. Moreover, the contamination is not only induced from the manufacturing operation, but also induced from inspection or measuring steps.

### SUMMARY OF THE INVENTION

According to an aspect of the present invention, there is provided a method of removing contaminations comprising providing a wafer, performing an inspection or a measuring step to the wafer, and performing a baking step to remove contaminations from the wafer after the inspection or measuring step.

According to the provided method of removing contaminations, the contamination source like lubrication oil deposited on the wafer in the inspection or measuring step in vacuum condition is re-vaporized by the baking step. Therefore the contaminations are successfully removed without impacting any features defined on the wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a method of removing contaminations provided by a first preferred embodiment of the present invention.

FIG. 2 is a column diagram comparing the defects found on the wafers before and after the baking step without the vacuum condition.

FIG. 3 is a column diagram comparing the defects found on the wafers before and after the baking step with the vacuum condition.

FIG. 4 is a flow chart of a method of removing contaminations provided by a second preferred embodiment of the present invention.

FIG. 5 is a flow chart of a method of removing contaminations provided by a third preferred embodiment of the present invention.

### DETAILED DESCRIPTION

Lubrication oil contaminations are found on the wafer surface after the critical dimension scanning electron microscope (CD-SEM) inspection or SEMVision review. This is because the lubrication oil is vaporized in a strong vacuum condition in the CD-SEM, but it re-deposit back into both the chamber and the wafer during removing the vacuum. The lubrication oil contaminations make discolor defect or micro bubble defect on the wafer and adversely affect film impurity. The contaminated wafers even impact other wafers which pass the same chamber. And the devices within the vicinity of the contaminations will likely be inoperable if such contaminations are not removed. Thus, it is necessary to clean contaminations from the wafer surface in a substantially complete manner without damaging the features defined on the wafer.

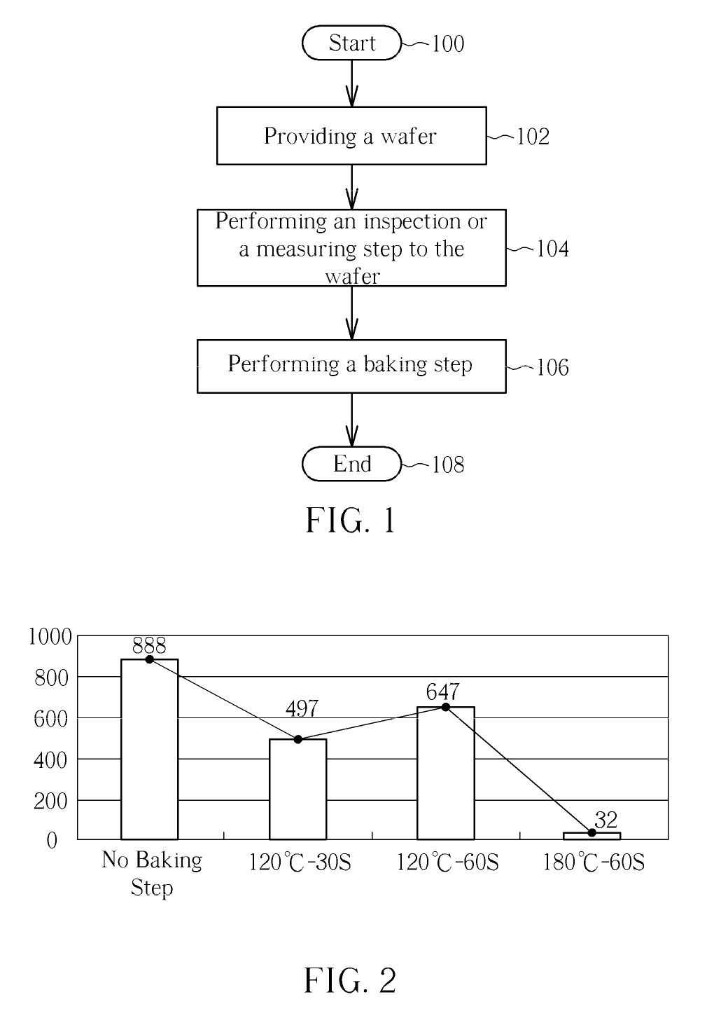

Please refer to FIG. 1, which is a flow chart of a method of removing contaminations provided by a first preferred embodiment of the present invention. As shown in FIG. 1, Step 100, Step 102, and Step 104 are sequentially performed:

Step 100: Start

Step 102: Providing a wafer.

Step 104: Performing an inspection or a measuring step to the wafer.

The inspection or measuring step includes scanning electron microscope (SEM), critical dimension scanning electron microscope (CD-SEM), scatterometry, atomic force microscopy (AFM) or critical dimension atomic force microscopy system (CD-AFM) inspection, thickness measuring, sheet resistance measuring or defect scanning/inspection steps. The aforementioned inspection or measuring steps may be performed in a vacuum condition. But it is not limited to include other proper metrology method. In the first preferred embodiment, the CD-SEM is employed to measure line-width of the layers formed on the wafer.

It is well-known that lubrication oil or other organic chemicals is always applied to ensure the performance of movement units of the CD-SEM apparatus. And the viscosity, which refers to the substance's resistance to flow, of the lubrication oil is crucial to the lubrication capacity of lubrication oil. It is conceivable that the viscosity of the lubrication oil is increased as the molecular weight of the lubrication oil increases. And the higher viscosity implies high resistance to the movement units of the inspection apparatus. Thus the lubrication oil of lower viscosity is more appropriate for the movement units of the inspection apparatus. However, during performing the inspection or measuring step, the wafer and the movement units may be put in a chamber in a strong vacuum condition, therefore the lower viscosity the lubrication oil has, the more easily vaporization occurs.

As mentioned above, the lubrication oil in the CD-SEM apparatus is vaporized during performing the inspection or measuring step, but it is deposited back on the inspected wafer and the chamber of the CD-SEM apparatus and cause contaminations. The lubrication oil contaminations on the wafer consequently cause discolor defect or micro bubble defect on the wafer and adversely affect film impurity. Moreover, the lubrication oil may be vaporized and re-deposited on chambers of other apparatus and contaminates other wafer which pass the same chamber. Thus, Step 106 and Step 108 are performed:

Step 106: Performing a baking step to remove contaminations from the wafer.

Step 108: End

The baking step can be performed by a conventional thermal apparatus without a vacuum condition. It is performed at a temperature between about 100° C. and about 180° C. for a duration of about few seconds to about few minutes. Please refer to FIG. 2, which is a column diagram comparing the defects found on the wafers before and after the baking step without the vacuum condition. In FIG. 2, the abscissa shows the condition of the baking step and the ordinate shows the defect amounts counted from the wafer. Accordingly, the baking step can be performed at 120° C. in 30 seconds, at 120° C. in 60 seconds, or 180° C. in 60 seconds. In the baking step, the lubrication oil deposited on the wafer is re-vaporized and thus removed from the wafer. As shown in FIG. 2, the defects found on the wafer after the baking step, that is performed at 180° C. in 60 seconds, is much less than that found on the wafer not undergone the baking step. In other words, the lubrication oil contaminations are removed from the wafer by the baking step.

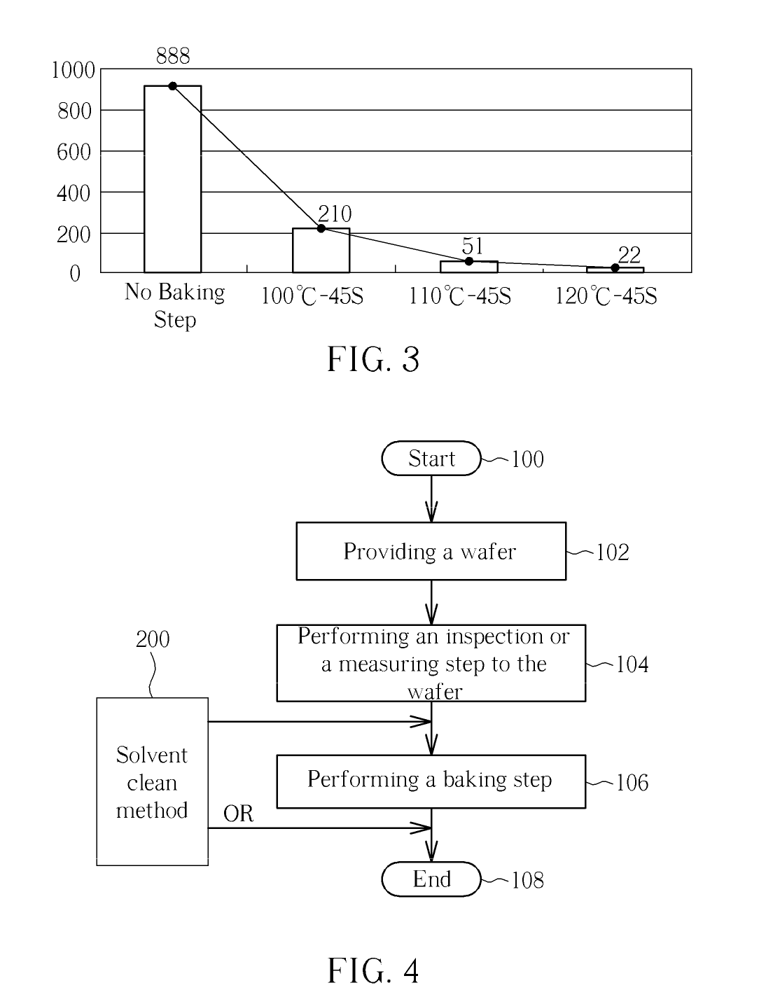

It is noteworthy that the baking step is preferably performed in a vacuum condition because the vaporization is apt to occur at low-pressured environment. Therefore the baking step with vacuum condition is performed at a temperature between about 100° C. and about 120° C. for a duration of about few seconds to about few minutes. Please refer to FIG. 3, which is a column diagram comparing the defects found on the wafers before and after the baking step with vacuum condition. In FIG. 3, the abscissa shows the condition of the baking step and the ordinate shows the defect amounts counted from the wafer. Accordingly, the baking step can be performed at 100° C. in 45 seconds, at 110° C. in 45 seconds, or 120° C. in 45 seconds. As shown in FIG. 3, the defects found on the wafer after the baking step, that is performed at 120° C. in 45 seconds, are much less than that found on the wafer not undergone the baking step. In other words, the lubrication oil deposited on the wafer is re-vaporized and thus the lubrication oil contaminations are removed from the wafer by the baking step.

Comparing FIG. 2 and FIG. 3, it is found that the baking step with the vacuum condition is performed at lower temperature and shorter duration while the result is even better. Therefore, those skilled in at art would easily realize that the baking step performed with the vacuum condition is more appropriate for the wafers with IC devices having lower thermal budget.

Please refer to FIG. 4, which is a flow chart of the method of removing contaminations provided by a second preferred embodiment of the present invention. Since Step 100 to Step 108 in the second preferred embodiment are similar with the steps described in the first preferred embodiment, those details are omitted in the interest of brevity. According to the second preferred embodiment, the method of removing contaminations further comprises a step of performing a solvent clean method 200 before or after Step 106 for further removing the lubrication oil contaminations. The solvent clean method 200 comprises reducing resist consumption (RRC) solvent, N-Methyl-2-pyrrolidone (NMP), or any other proper organic solvent. Since the lubrication oil is an organic material, it can be removed by the organic solvent as mentioned above.

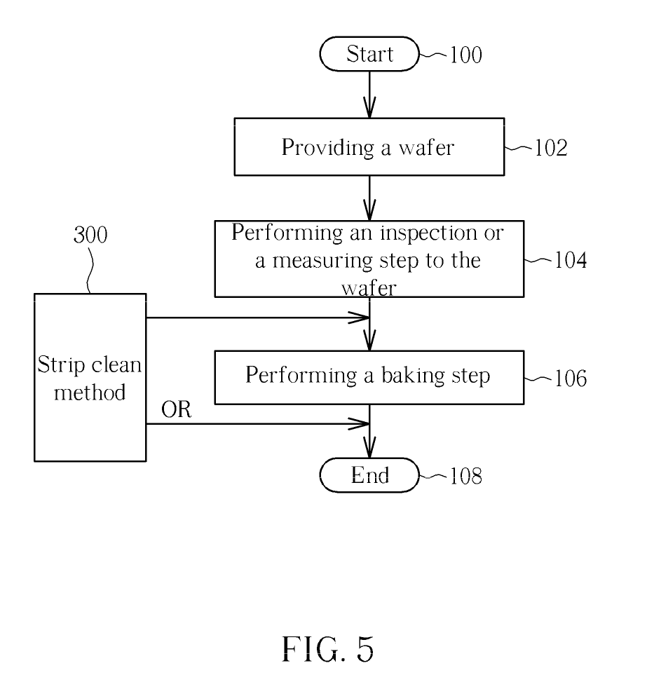

Please refer to FIG. 5, which is a flow chart of the method of removing contaminations provided by a third preferred embodiment of the present invention. Since Step 100 to Step 108 in the third preferred embodiment are similar with those steps in the first preferred embodiment, those details are also omitted. According to the third preferred embodiment, the method of removing contaminations further comprises a step of performing a strip clean method 300 before or after Step 106 for further removing the lubrication oil contaminations. The strip clean method 300 comprises Caroz acid or plasma. According to the second and third preferred embodiments, the results of removing the lubrication oil contaminations can be further improved due to the introduction of the solvent clean method and the strip clean method.

Furthermore, it is noteworthy that since the contaminations are caused by the lubrication oil which is vaporized in the vacuum condition, the method of removing contaminations provided by the present invention can be not only applied after performing the inspection or measuring steps, but also can be applied after any step in the semiconductor manufacturing process that performed in a vacuum condition.

According to the provided method of removing contaminations, the lubrication oil deposited on the wafer in the inspection or measuring step or the in vacuum condition is re-vaporized by the baking step. Therefore the contaminations are successfully removed without impacting any features defined on the wafer.

Those skilled in the art will readily observe that numerous modifications and alterations of the device and method may be made while retaining the teachings of the invention.

What is claimed is:

1. A method of removing contaminations comprising:
providing a wafer;
performing an inspection or a measuring step to the wafer; and
performing a baking step to remove contaminations from the wafer after the inspection or measuring step.

2. The method of claim 1, wherein the inspection or measuring step comprises scanning electron microscope (SEM), critical dimension scanning electron microscope (CD-SEM), scatterometry, atomic force microscopy (AFM), critical dimension atomic force microscopy system (CD-AFM) inspection, thickness measuring, sheet resistance measuring or defect scanning/inspection step.

3. The method of claim 2, wherein the inspection or measuring step is performed in a vacuum condition.

4. The method of claim 1, wherein the baking step is performed in a duration of 1 second to 60 minutes.

5. The method of claim 1, wherein the baking step is performed without a vacuum condition.

6. The method of claim 5, wherein the baking step is performed at a temperature between 100° C. and 180° C.

7. The method of claim 1, wherein the baking step is performed in a vacuum condition.

8. The method of claim 7, wherein the baking step is performed preferably at a temperature between 100° C. and 120° C.

9. The method of claim 1 further comprising a step of performing a solvent clean method.

10. The method of claim 9, wherein the solvent clean method comprises reducing resist consumption (RRC) solvent, or N-Methyl-2-pyrrolidone (NMP).

11. The method of claim 1 further comprising a step of performing a strip clean method.

12. The method of claim 11, wherein the strip clean method comprises Caroz acid or plasma.
